(19) United States
(12) Patent Application Publication
(10) Pub. No.: US 2013/0222936 A1
(43) Pub. Date: Aug. 29, 2013

(54) COLOR FILTER SUBSTRATE AND METHOD FOR PRODUCING SAME

(71) Applicant: Takafumi Kawanishi, Osaka (JP)

(72) Inventor: Takafumi Kawanishi, Osaka (JP)

(73) Assignee: SHARP KABUSHIKI KAISHA, Osaka (JP)

(21) Appl. No.: 13/881,922

(22) PCT Filed: Oct. 25, 2011
(86) PCT No.: PCT/JP2011/074483

§ 371 Date: Apr. 26, 2013

(30) Foreign Application Priority Data
Nov. 2, 2010 (JP) 2010-246586

(51) Int. Cl. G02B 5/20; G03F 7/00

(52) U.S. Cl. CPC G02B 5/20; G03F 7/0007
USPC 359/891; 430/321

(57) ABSTRACT

The present invention provides a color filter substrate and a method for producing the same, in which the uniformity in thickness of a color filter can be improved. The present invention is a method for producing a color filter substrate, the method including: a step for forming a photoresist film; a step for conducting an exposure process on the photoresist film through a photomask; a step for forming a bank defining an opening by developing the exposed photoresist film; and a step for discharging ink into the opening. The photomask has a transparent region, a light-shielding region, and a translucent region. The transmittance of the translucent region is less than the transmittance of the transparent region and is greater than the transmittance of the light-shielding region, and the translucent region is provided between the transparent region and the light-shielding region along an outline of the transparent region and the light-shielding region, respectively.

### TECHNICAL FIELD

The present invention relates to a color filter substrate and a method for manufacturing the same. More specifically, the present invention relates to a color filter substrate and a method for manufacturing the same suitable for forming a color filter using the inkjet method.

### BACKGROUND ART

Color filter substrates are widely used in flat panel displays (FPD) such as liquid crystal displays. A color filter substrate generally includes a transparent substrate, a black matrix (BM), and color filters (CF). The BM and CFs are formed on the transparent substrate.

Currently, CFs are mainly formed using photolithography. However, techniques for forming CFs using the inkjet method are being developed (refer to Patent Document 1, for example). Using the inkjet method, it is possible to reduce capital investment and material costs, and thus, it is possible to reduce the cost of the color filter substrate. The inkjet method can be applied to a large color filter substrate with ease.

Techniques for controlling the shape and liquid-repellence of BMs used in the inkjet method are disclosed (refer to Patent Documents 2 and 3, for example). In these techniques, photolithography is used to form the BM, and it is necessary to conduct exposure a plurality of times in order to form the BM.

### RELATED ART DOCUMENTS

### Patent Documents

Patent Document 1: Japanese Patent Application Laid-Open Publication No. 2009-69726

Patent Document 2: Japanese Patent Application Laid-Open Publication No. 2009-145650

Patent Document 3: Japanese Patent Application Laid-Open Publication No. 2009-145910

### SUMMARY OF THE INVENTION

### Problems to be Solved by the Invention

Here, with reference to FIGS. 15 to 17, a manufacturing method for a color filter substrate of Comparison Example 1, which the inventor of the present invention has studied, will be described. FIG. 15 is a cross-sectional view that schematically shows a BM manufactured by the manufacturing method for a color filter substrate of Comparison Example 1. FIG. 16 is an SEM photograph that shows a cross-section of the BM manufactured by the manufacturing method for the color filter substrate of Comparison Example 1. FIG. 17 is a drawing that schematically shows a manufacturing step of the color filter substrate of Comparison Example 1, and specifically shows an ink discharge step.

First, as shown in FIG. 15, a BM 113 with an opening 116 was formed on a transparent substrate 111 using photolithography. The cross-sectional shape of the BM 113, as shown in FIG. 16, was a rectangle or a trapezoid. Next, plasma treatment was conducted in an atmosphere that includes oxygen, giving hydrophilic properties to an exposed portion 117 of the substrate 111 (the exposed portion inside the opening 116). Next, plasma treatment using a fluorine-containing gas such as CF₄ was conducted, thus giving water-repellence to a surface of the BM 113. Next, using the inkjet method, red, blue, or green ink 118 was discharged into the opening 116 of the BM 113. At this time, the BM 113 functions as a bank that stops the flow of the ink 118. Also, as shown in FIG. 17, the ink 118 has a convex shape in which the central portion thereof is thick. Then, a step of pre-baking and a step of post-baking were conducted, thus forming a CF 119.

FIG. 18 shows a three dimensional image of the CFs 119 and the BM 113 using white light interferometry. FIG. 19 is a graph that shows a thickness distribution of one CF 119. As shown in FIGS. 18 and 19, in Comparison Example 1, like the ink 118, each CF 119 also had a convex shape, and the thicknesses (shape) of the CFs 119 were not uniform. Therefore, if a liquid crystal panel was assembled using the color filter substrate manufactured by the above-mentioned method, the thickness of the liquid crystal layer was not uniform in each subpixel. As a result, optical properties of a liquid crystal display that includes the above-mentioned liquid crystal panel, or in other words, the display properties, were worse than if the CFs were formed using photolithography.

As described above, if the inkjet method is used, CFs are particularly susceptible to having non-uniform thicknesses.

The present invention was made in view of the above-mentioned situation, and an object thereof is to provide a color filter substrate and a manufacturing method therefor that can improve the uniformity in thickness of the color filters.

### Means for Solving the Problems

The inventor of the present invention has conducted various studies on a manufacturing method for a color filter substrate that can improve the uniformity in thickness of the color filters, and has focused on the shape of the bank that stops the flow of ink. A photomask for forming the bank was provided with a transparent region, a light-shielding region, and a translucent region having a smaller transmittance than the transparent region and a greater transmittance than the light-shielding region, and the translucent region was provided between the transparent region and the light-shielding region along respective outlines of the transparent region and the light-shielding region. It was discovered that by doing so, the main body part of the bank can be formed corresponding to the transparent region or the light-shielding region, and that an eve corresponding to the translucent region can be formed on the bank, thus solving the above-mentioned problem and arriving at the present invention.

In other words, one aspect of the present invention is a manufacturing method for a color filter substrate that includes: (1) forming a photoresist film; (2) conducting an exposure process on the photoresist film through a photomask; (3) forming a bank with an opening by developing the photoresist film that underwent the exposure process; and (4) discharging ink into the opening, wherein the photomask has a transparent region, a light-shielding region, and a translucent region, wherein a transmittance of the translucent region is less than a transmittance of the transparent region and greater than a transmittance of the light-shielding region, and wherein the translucent region is provided between the transparent region and the light-shielding region along outlines of the transparent region and the light-shielding region, respectively.

As long as such steps are included as necessary steps, the manufacturing method for the color filter substrate has no special limitation in terms of other steps. Preferred embodiments of the manufacturing method for the color filter substrate are described in detail below. The various embodiments shown below may be appropriately combined.

The transparent region does not necessarily need to completely transmit light of all wavelengths. The transmittance of the transparent region to light with a wavelength of 350 to 450 nm is preferably 90 to 95%.

The light-shielding region does not necessarily need to completely block light of all wavelengths. The transmittance of the light-shielding region to light with a wavelength of 350 to 450 nm is preferably 1% or less.

The transmittance of the translucent region to light with a wavelength of 350 to 450 nm is preferably 2 to 80%.

It is preferable that the translucent region be a half-tone region or a grey-tone region. With this configuration, the transmittance of the translucent region can be made less than that of the transparent region and greater than that of the light-shielding region, with greater ease and reliability. Therefore, it is possible to realize the present invention with greater ease and reliability.

It is preferable that the bank have a lower part, and an upper part that includes an overhang that hangs over the opening, and that, in the aforementioned step (4), the ink be discharged until the ink is in contact with a face of the overhang on a side of the substrate.

In another preferred embodiment (also referred to as a first embodiment below), the opening is a first opening, in the aforementioned step (3) the first opening and a second opening are formed in the bank, the bank has a lower part and an upper part, the upper part includes a first overhang that hangs over the first opening and a second overhang that hangs over the second opening, the ink is a first ink, in the aforementioned step (4) a second ink of a different color from the first ink is discharged in the second opening in addition to the first ink being discharged, and the translucent region is provided in order to form the first overhang and the second overhang. With this configuration, it is possible to improve the uniformity in thickness of the color filters of a plurality of colors.

In the first embodiment, of the translucent region, a transmittance of a region for forming the second overhang (second transmittance) may be different from or substantially the same as a transmittance of a region for forming the first overhang (first transmittance). If the two are different from each other, then color filters of a plurality of colors with different thicknesses can be formed with ease, and the shapes thereof can be optimized with ease. If the first transmittance and the second transmittance are substantially the same, then color filters of a plurality of colors with thicknesses that are substantially the same can be formed with ease, and the shapes thereof can be optimized with ease. If the two are different from each other, then the difference between the first transmittance and the second transmittance to light with a wavelength of 350 to 450 nm may be 1% or greater, and if the two are substantially the same as each other, then the difference between the first transmittance and the second transmittance to light with a wavelength of 350 to 450 nm may be less than 1%.

Another aspect of the present invention is a color filter substrate that includes: a substrate; a bank with an opening formed therein; and a color filter formed in the opening, wherein the color filter and the bank are formed on the substrate, wherein the bank has a lower part, and an upper part that includes an overhang that hangs over the opening, and wherein the color filter has a shape that is convex in a direction opposite to the substrate, the color filter being in contact with a face of the overhang on a side of the substrate.

The color filter substrate can be manufactured using the aforementioned manufacturing method for the color filter substrate. Therefore, the uniformity in thickness of the color filters can be improved.

As for a configuration of the color filter substrate, as long as such components are formed as necessary parts, there is no special limitation on other components. Preferred embodiments of the color filter substrate are described in detail below. The various embodiments shown below may be appropriately combined.

It is preferable that the bank not include a liquid-repellent substance. As a result, after the step of forming a bank, a step of surface treatment can be conducted on the bank. Thus, desired properties can be provided to the surface of the bank (lyophilic properties or liquid-repellent properties).

In another preferred embodiment (also referred to as a second embodiment below), the opening, the color filter, and the overhang are respectively a first opening, a first color filter, and a first overhang, the bank further has a second opening formed therein, the color filter substrate further includes a second color filter formed in the second opening and on the substrate, the upper part further has a second overhang that hangs over the second opening, a color of the second color filter differs from a color of the first color filter, and the second color filter has a shape that is convex in a direction opposite to the substrate, the second color filter being in contact with a face of the second overhang on the side of the substrate. With this configuration, it is possible to improve the uniformity in thickness of the color filters of a plurality of colors.

In the second embodiment, a thickness (second thickness) of the second overhang may be different or substantially the same as a thickness (first thickness) of the first overhang. If the two are different from each other, then color filters of a plurality of colors with different thicknesses can be formed with ease, and the shapes thereof can be optimized with ease. If the first thickness and the second thickness are substantially the same, then color filters of a plurality of colors with thicknesses that are substantially the same can be formed with ease, and the shapes thereof can be optimized with ease. If the two are different from each other, then the difference between the first thickness and the second thickness may be 0.1 μm or greater, and if the two are substantially the same as each other, then the difference between the first thickness and the second thickness may be less than 0.1 μm.

### Effects of the Invention

According to the present invention, a color filter substrate that can improve the uniformity in thickness of the color filters and a manufacturing method therefor can be realized.

### BRIEF DESCRIPTION OF THE DRAWINGS

FIG. 1 is a drawing that schematically shows a manufacturing step of a color filter substrate of Embodiment 1, and specifically, a step of forming a photoresist film.

FIG. 2 is a drawing that schematically shows a manufacturing step of the color filter substrate of Embodiment 1, and specifically, a step of exposure.

FIG. 3 is a schematic plan view of a photomask used in a manufacturing step of the color filter substrate of Embodiment 1.

FIG. 4 is a magnified view of the photomask shown in FIG. 3, and specifically shows a half-tone region and a light-shielding region.

FIG. 5 is a schematic cross-sectional view of FIG. 3 along the line A1-A2.

FIG. 6 is a schematic plan view of a bank manufactured by a manufacturing method for the color filter substrate of Embodiment 1.

FIG. 7 is a schematic cross-sectional view of FIG. 6 along the line B1-B2.

FIG. 8 is a drawing that schematically shows a manufacturing step of the color filter substrate of Embodiment 1, and specifically, a step of ink discharge.

FIG. 9 is a schematic cross-sectional view of an eve of a bank in FIG. 8 and a vicinity thereof.

FIG. 10 is a schematic cross-sectional view of the color filter substrate manufactured by the manufacturing method of the color filter substrate of Embodiment 1.

FIG. 11 is a different schematic cross-sectional view of the color filter substrate manufactured by the manufacturing method of the color filter substrate of Embodiment 1.

FIG. 12 is a photograph (reference photograph) taken by a scanning electron microscope (SEM) that shows a cross-section of a bank manufactured by a manufacturing method of a color filter substrate that differs from Embodiment 1.

FIG. 13 is a schematic plan view of a photomask used in a manufacturing step of the color filter substrate of Embodiment 2.

FIG. 14 is a schematic cross-sectional view of the color filter substrate manufactured by the manufacturing method of the color filter substrate of Embodiment 3.

FIG. 15 is a schematic cross-sectional view of a BM manufactured by a manufacturing method for a color filter substrate of Comparison Example 1.

FIG. 16 is a photograph taken by a scanning electron microscope (SEM) that shows a cross-section of a BM manufactured by a manufacturing method for the color filter substrate of Comparison Example 1.

FIG. 17 is a drawing that schematically shows a manufacturing step of the color filter substrate of Comparison Example 1, and specifically, a step of ink discharge.

FIG. 18 is a three dimensional image generated by white light interferometry of a CF and a BM manufactured by the manufacturing method of the color filter substrate of Comparison Example 1.

FIG. 19 is a graph that shows a thickness distribution of the CF manufactured by the manufacturing method of the color filter substrate of Comparison Example 1.

### DETAILED DESCRIPTION OF EMBODIMENTS

Embodiments are shown below and the present invention is described in further detail with reference to the drawings, but the present invention is not limited to these embodiments.

### Embodiment 1

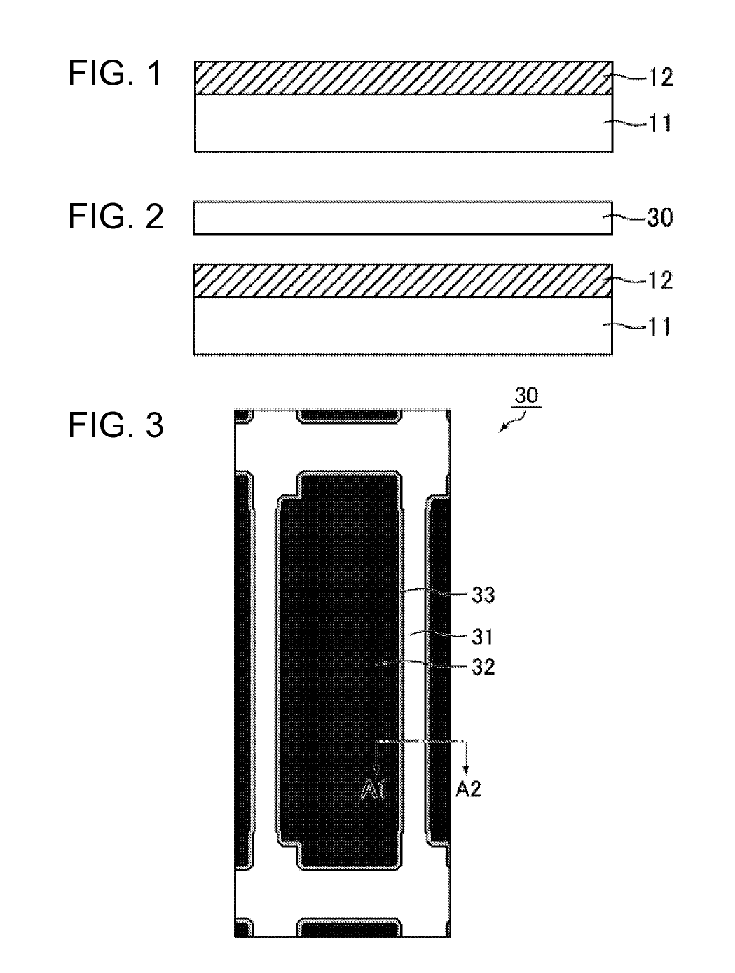

A manufacturing method of a color filter substrate according to Embodiment 1 will be described with reference to FIGS. 1 to 12.

First, a liquid or sheet photoresist material is coated or bonded onto a transparent substrate 11 such as a glass substrate. Then, as necessary, a step of pre-baking and a step of post-baking are conducted in this order, and as shown in FIG. 1, a light-shielding photoresist film 12 is formed.

The thickness of the photoresist film 12 is 1.0 to 3.0 μm (preferably 2.0 to 2.5 μm). The photoresist material is of a negative type. Although the color of the photoresist material and the bank, which is mentioned below, has no special limitation, the color is preferably black, and it is preferable that a black pigment be included in the photoresist material and the bank to be mentioned below. As a result, excellent contrast can be attained.

Next, as shown in FIG. 2, an electromagnetic wave (ultraviolet ray, for example) is radiated onto the photoresist film 12 through a photomask 30. The amount of exposure in this step is set to 50 to 200 mJ/cm² (preferably 100 to 150 mJ/cm²), for example.

There is no special limitation on types of exposure device that can be used in the present embodiment, and a stepper, a minor projection exposure device, and a proximity exposure device can be used, for example.

Also, an electron beam may be radiated instead of an electromagnetic wave.

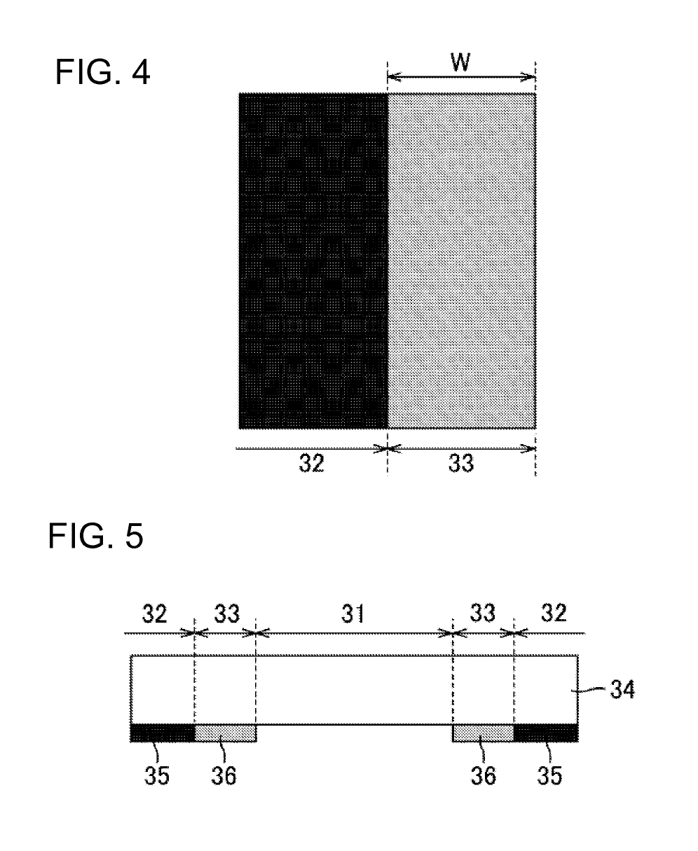

As shown in FIGS. 3 and 4, the photomask 30 has a transparent region 31, light-shielding regions 32, and half-tone regions (HT region) 33, which are translucent regions.

The HT regions 33 are provided between the transparent region 31 and the light-shielding regions 32 along the respective outlines of the transparent region 31 and the light-shielding regions 32. The light-shielding regions 32 are rectangular. The transparent region 31 is a region other than the light-shielding regions 32 and the HT regions 33, and is in a grid pattern. In this way, each HT region 33 is provided along an edge of each light-shielding region 32. Also, each HT region 33 is formed along the edge of one of the regions 31 and 32, and the other of the regions 31 and 32 corresponds to the region that does not include the one of the regions 31 and 32 and the HT region 33.

A width W of the HT region 33 is 0.5 to 10 μm (preferably 1.0 to 3.0 μm).

As shown in FIG. 5, the photomask 30 has a transparent substrate (support body) 34, light-shielding layers 35, and translucent layers 36. The light-shielding layers 35 and the translucent layers 36 are each patterned on the substrate 34.

The substrate 34 transmits substantially all radiated light. Specifically, the transmittance of the substrate 34 to light of a wavelength of 350 to 450 nm is substantially 92%. The substrate 34 is made of a glass such as a soda-lime glass or a synthetic quartz glass.

The light-shielding layers 35 are formed by patterning a light-shielding thin film. The light-shielding layers 35 block substantially all radiated light. Specifically, the transmittance of the light-shielding layers 35 to light of a wavelength of 350 to 450 nm is substantially 0%. The light-shielding layers 35 are made of a metal such as chromium.

The light-shielding layers 35 are formed in all light-shielding regions 32 and are not formed in the transparent region 31. Therefore, in the transparent region 31, only the substrate 34 is present, and thus, almost all radiated light is transmitted through the transparent region 31. Also, the light-shielding regions 32 block substantially all radiated light.

The translucent layers 36 are formed by patterning a translucent thin film. The translucent layers 36 transmit some radiated light. Specifically the transmittance of the translucent layers 36 to light of a wavelength of 350 to 450 nm is between 20% (preferably 30%) and 80% (preferably 70%) inclusive, for example. The translucent layers 36 are made of chromium, molybdenum silicide, tantalum, aluminum, an oxide that includes an element such as silicon, a nitride, a carbide, a nitroxide, a carbonitride, or the like.

The translucent layers 36 are formed in the entirety of the HT regions 33. Therefore, the HT regions 33 transmit some radiated light.

The transparent region 31, the light-shielding regions 32, and the HT regions 33 have the same transmittance as the substrate 34, the light-shielding layers 35, and the translucent layers 36, respectively. Therefore, the transmittance of the photomask 30 increases in the order of the light-shielding region 32, the HT region 33, and the transparent region 31.

Next, a developer such as a potassium hydroxide aqueous solution is used in order to develop the exposed photoresist film 12, thus forming a photoresist pattern. As a result, most portions of the photoresist film 12 exposed through the transparent region 31 remain. By contrast, some of the portion of the photoresist film 12 exposed through the HT region 33 is removed, and the parts of the photoresist film 12 corresponding to the light-shielding region 32, or in other words, the non-exposed portions are substantially all removed.

Next, an electromagnetic wave (ultraviolet ray, for example) or an electron beam is radiated onto the photoresist pattern.

Next, a step of baking is conducted at 160 to 300° C. (preferably 200 to 260° C.).

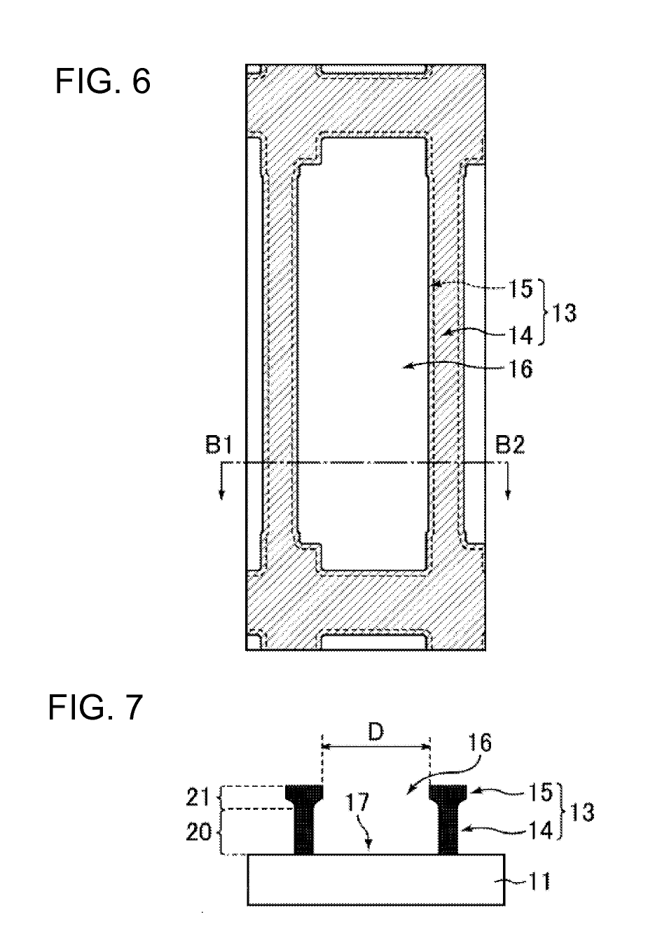

With the steps above, as shown in FIGS. 6 and 7, a bank 13 is formed on the substrate 11.

A plurality of rectangular openings 16 are formed in the bank 13, and the bank 13 includes a grid shaped main body part 14 and eves (overhangs) 15. The eves 15 protrude from an upper part of the main body part 14 (part opposite to the substrate 11) to the side of the openings 16 (towards the openings 16). In other words, the bank 13 has a lower part 20 (part on the side of the substrate 11) and an upper part 21 (part opposite to the substrate 11) that includes the eve 15. The eve 15 hangs over the opening 16 to a greater degree than the lower part 20. The thickness of the eve 15, or more specifically, the thickness of the part of the eve 15 in contact with the main body part is approximately 0.2 to 0.5 μm. The width of the eve 15 is approximately 3 to 30 μm.

The main body part 14 is formed corresponding to the part of the photoresist film 12 exposed through the transparent region 31, and the eves 15 are formed corresponding to the part of the photoresist film 12 exposed through the HT regions 33. The openings 16 are formed in parts of the photoresist film 12 that are removed.

In other words, the light-shielding regions 32 of the photomask 30 are provided corresponding to the openings 16 in order to form the openings 16, the transparent region 31 is provided corresponding to the main body part 14 in order to form the main body part 14, and the HT regions 33 are provided corresponding to the eves 15 in order to form the eves 15.

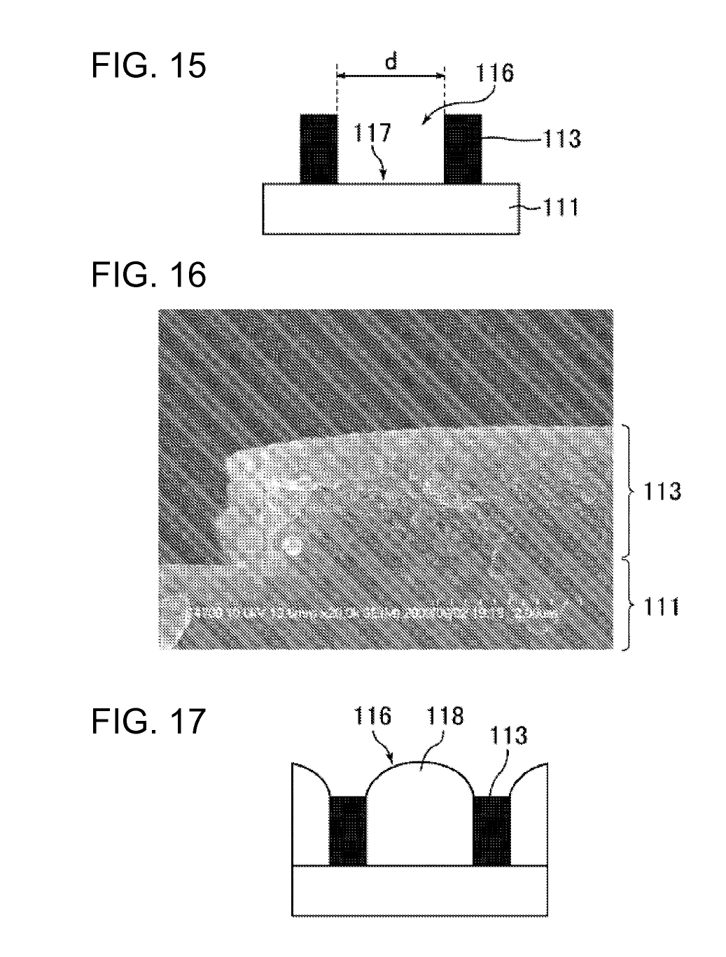

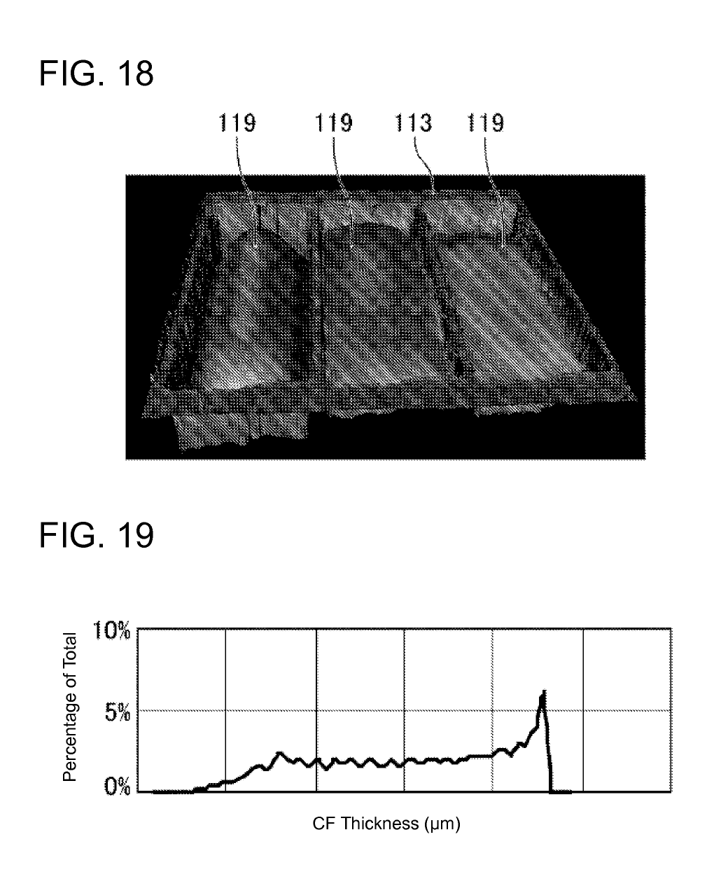

As shown in FIGS. 7 and 15, a distance D between eves 15 that face each other is substantially the same as a distance d between parts of the BM 113 that face each other in Comparison Example 1.

Next, plasma treatment is conducted under an atmosphere that includes oxygen. As a result, exposed parts 17 of the substrate 11 (exposed parts in the openings 16) are provided with lyophilic properties (preferably hydrophilic properties).

Next, plasma treatment using a fluorine-containing gas such as CF₄ is conducted. As a result, the surface of the bank 13 is made liquid-repellent (preferably water-repellent). A liquid-repellent substance may be mixed into the photoresist material instead of conducting plasma treatment, but it is preferable that the photoresist material and the bank 13 not include a liquid-repellent substance.

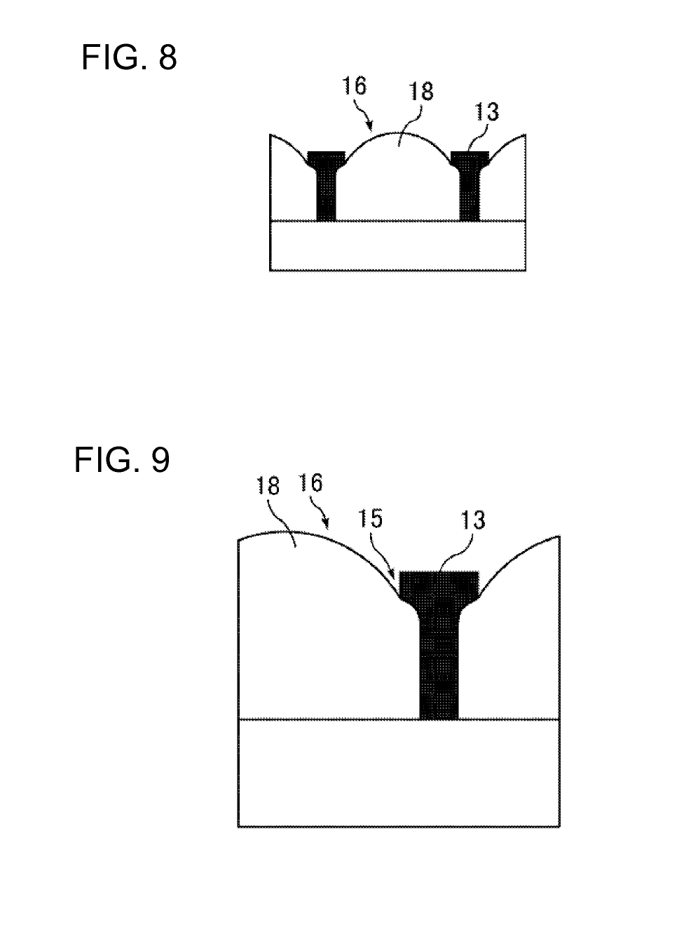

Next, an inkjet device is used in order to discharge red, blue, and green ink 18 into the openings 16, or in other words, on the exposed parts 17. As shown in FIG. 8, the ink 18 spreads inside the openings 16 until it is stopped by the bank 13, and as a result, each opening 16 is filled by the ink 18. In this manner, the bank 13 has a function of stopping the spread of the ink 18, and also functions as a black matrix. Also, the ink 18 has a shape that is convex in the direction opposite to the substrate 11 due to surface tension. The peak of the ink 18 becomes much greater in height than the bank 13; the height of the peak of the ink 18 from the surface of the substrate 11 is approximately 10 to 15 μm, which is 5 times to 20 times greater than the height of the bank 13.

Also, as shown in FIG. 9, the ink 18 is in contact with bottom faces of the eves 15 (face thereof on the side of the substrate 11, facing the substrate 11). As a result, the surface of the ink 18 is pressed towards the substrate 11 by the eves 15. In other words, pressure towards the substrate 11 is applied on the ink 18. As a result, compared to Comparison Example 1, the surface of the ink 18 can be made more flat. Also, it is possible to prevent different color inks 18 from overflowing the bank 13 and mixing. In addition, it is possible to prevent a gap from forming between the color filter (CF) 19 to be mentioned below and the bank 13 due to the ink 18 not spreading to the bank 13.

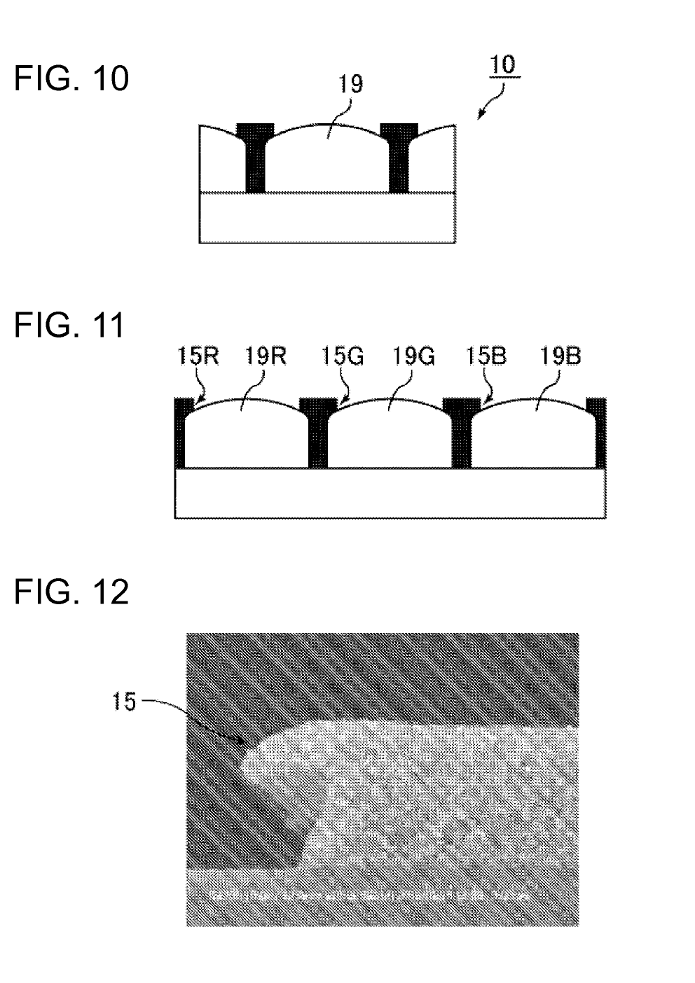

Next, a step of pre-baking and a step of post-baking are conducted in this order. As a result of these steps, the solvent in the ink 18 evaporates, and as shown in FIG. 10, red, blue, and green CFs 19 are formed. The CFs 19 are divided by the bank 13. In this manner, the color filter substrate 10 is completed.

The CF 19 has a shape that is convex in the direction opposite to the substrate 11. The CF 19 is thinner than the ink 18 due to the solvent having evaporated, but is still in contact with the bottom faces of the eves 15.

As shown in FIG. 11, the CFs of each color (red CF 19R, green CF 19G, blue CF 19B) have substantially the same thickness (height) as each other. Also, the eves (eve 15R, eve 15G, eve 15B) for the CFs of each color have substantially the same thickness as each other, and as a result, the shape of the CFs of each color with the above-mentioned thickness can be optimized with ease.

FIG. 12 shows an SEM photograph (reference photograph) of a cross-section of a bank manufactured by the manufacturing method for a color filter substrate that differs from the present embodiment. Like the bank shown in FIG. 12, it is possible to form an eve 15 on an edge of the bank 13 in the present embodiment also. Therefore, as stated above, the surface of the ink 18 can be made flat. As a result, the surface of the CF 19 can also be made flat, and the uniformity in thickness of the CF 19 can be improved.

Also, the CF 19 has equivalent color properties (optical properties) to CFs formed by photolithography. As a result, when using the color filter substrate 10 in a liquid crystal display, the liquid crystal display can realize equivalent optical properties (display properties) to when a color filter substrate with CFs formed by photolithography is used.

There is no special limitation on the applications of the color filter substrate 10, and the color filter substrate 10 can be used in an FPD such as a liquid crystal display or an organic EL display, for example.

Also, in the present embodiment, the number of exposures needed to form the bank 13 is one, and in the techniques disclosed in Patent Documents 2 and 3, the number of necessary exposures is two. Thus, according to the present embodiment, the number of steps, or in other words, the cost can be decreased compared to the techniques disclosed in Patent Documents 2 and 3.

Also, in the present embodiment, after the step of forming the bank 13, a step of treating the surface of the bank 13 is conducted. Thus, desired properties can be provided to the surface of the bank 13 (lyophilic properties or liquid-repellent properties). On the other hand, with the techniques disclosed in Patent Documents 2 and 3, a BM resin composition including a liquid-repellent substance (ink-repellent substance) is used. As a result of this difference in manufacturing process, with the techniques disclosed in Patent Documents 2 and 3, it is impossible to make the surface of the CF 19 as flat as in the present embodiment.

In the present embodiment, the photoresist material may be positive. In such a case, the pattern of the transparent region 31 and the pattern of the light-shielding regions 32 simply need to be switched.

The photoresist material and the bank 13 may be transparent, but in such a case, it is preferable that a light-shielding film be provided separately. This light-shielding film may be formed by patterning a light-shielding thin film (a metal film such as chromium, for example). After forming the light-shielding film, a transparent bank 13 may be formed.

There is no special limitation on the types and number of colors of the CF 19, which can be appropriately set. For example, the CFs 19 may include four colors of red, blue, green, and yellow, the CFs 19 may include four colors of red, blue, green, and uncolored, the CFs 19 may include five colors of red, blue, green, yellow, and cyan, or the CFs 19 may include three colors of yellow, cyan, and magenta.

### Embodiment 2

The present embodiment is the same as Embodiment 1 with the exception of the following points. In the present embodiment, a photomask 230 is used instead of the photomask 30 in the step of exposure.

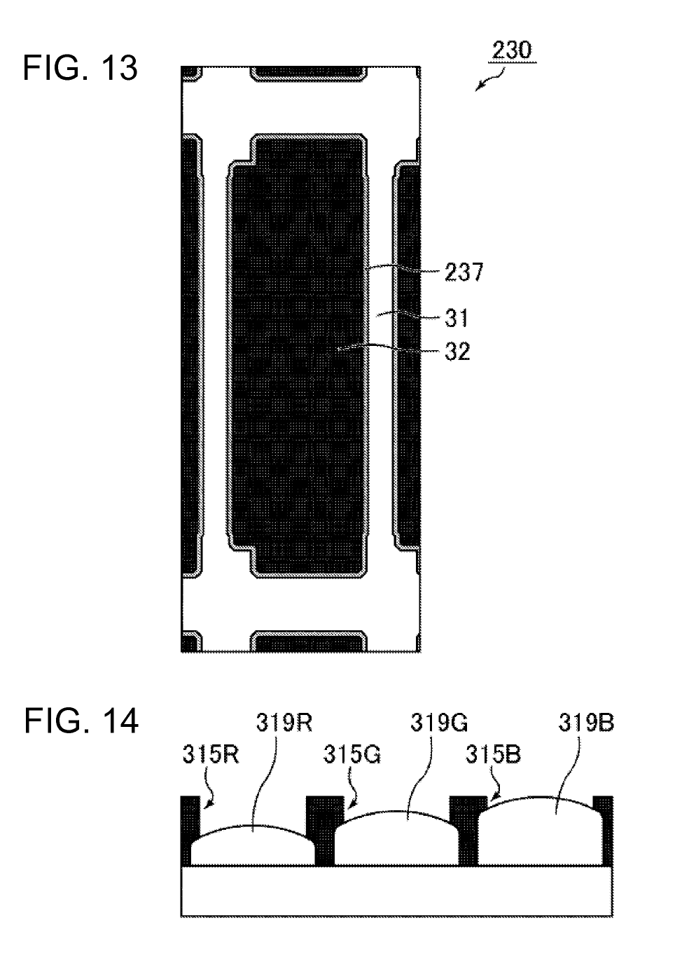

As shown in FIG. 13, the photomask 230 is the same as the photomask 30 except that the photomask 230 has grey-tone (GT) regions 237 as the translucent regions instead of the HT regions 33. The GT regions 237 have light-shielding parts and a transparent part smaller than the resolution limit of the exposure device. The light-shielding parts include a light-shielding layer, like the light-shielding region 32. In other words, the light-shielding parts are formed using the above-mentioned light-shielding thin film. The transparent part does not include a light-shielding layer, and includes only a substrate 34. Therefore, the transparent part transmits almost all radiated light. On the other hand, the light-shielding part includes a light-shielding layer and thus, blocks substantially all radiated light. In other words, the GT region 237 transmits some radiated light.

The transmittance of the GT region 237 to light of a wavelength of 350 to 450 nm is substantially a few percentage points. Therefore, the transmittance of the photomask 230 increases in the order of the light-shielding region 32, the GT region 237, and the transparent region 31.

There is no special limitation on the pattern of the transparent part of the GT region 237, and a slit pattern, a dot pattern, a minute pattern, or the like may be used, for example. The transparent part is smaller than the resolution limit of the exposure device, and thus, it is possible to allow the eves 15 to be formed without the pattern of the transparent part being transferred thereto. Therefore, the surface of the CFs can be flattened, and the uniformity in thickness of the CFs can be improved in the present embodiment also.

### Embodiment 3

The present embodiment is the same as Embodiment 1 with the exception of the following points. The photomask used in the exposure step of the present embodiment differs for each CF in terms of the types, transmittances, and widths of the translucent regions. In other words, the translucent regions of the photomask used in the present embodiment include a plurality of regions that differ in at least one of the type of pattern, the transmittance, and the width. With this configuration, it is possible to optimize the shape of the eve (thickness, for example) for each color of the CF. This is because, in general, the optimal shape for the eve differs depending on the ink color (type).

For example, a photomask used in the present embodiment may have an HT region and a GT region. As a result, it is possible to provide different transmittances for the HT region and the GT region with ease. Thus, it is possible to optimize the shape of the eves for each color with greater ease.

In the present embodiment, the thicknesses (heights) of CFs of each color differ from each other. More specifically, the average thickness and the maximum thickness (thickness at the peak) of CFs of each color differ from each other. In addition, the thicknesses of the eves for the CFs of each color differ from each other, and in the eves for the CFs of each color, the thickness of a part thereof in contact with the main body part is set within a range of approximately 0.2 to 0.5 μm. For example, as shown in FIG. 14, a green CF 319G is thicker than a red CF 319R, and a blue CF 319B is thicker than the CF 319G. Also, an eve 315G for the green CF is thicker than an eve 315B for the blue CF, and an eve 315R for the red CF is thicker than the eve 315G. By forming the eves 315R, 315G, and 315B, it is possible to optimize the shape of the CFs of each color having the above-mentioned thicknesses with ease.

The present application claims priority to Patent Application No. 2010-246586 filed in Japan on Nov. 2, 2010 under the Paris Convention and provisions of national law in a designated State. The entire contents of which are hereby incorporated by reference.

### DESCRIPTION OF REFERENCE CHARACTERS

10 color filter substrate

11 transparent substrate

12 photoresist film

13 bank

14 main body part

15, 15R, 15G, 15B, 315R, 315G, 315B eve (overhang)

16 opening

17 exposed portion

18 ink

19 color filter (CF)

19R, 319R red color filter (CF)

19G, 319G green color filter (CF)

19B, 319B blue color filter (CF)

20 lower part

21 upper part

30, 230 photomask

31 transparent region

32 light-shielding region

33 half-tone region (HT region)

34 substrate (support body)

35 light-shielding layer

36 translucent layer

237 grey-tone (GT) region

1. A manufacturing method for a color filter substrate, comprising:
(a) forming a photoresist film;
(b) conducting an exposure process on the photoresist film through a photomask;
(c) forming a bank defining an opening by developing the photoresist film that underwent the exposure process; and
(d) discharging ink into the opening,
wherein the photomask has a transparent region, a light-shielding region, and a translucent region,
wherein a transmittance of the translucent region is less than a transmittance of the transparent region and greater than a transmittance of the light-shielding region, and
wherein the translucent region is provided between the transparent region and the light-shielding region along outlines of the transparent region and the light-shielding region, respectively.

2. The manufacturing method for a color filter substrate according to claim 1, wherein the translucent region is a half-tone region or a grey-tone region.

3. The manufacturing method for a color filter substrate according to claim 1,
wherein the bank has a lower part, and an upper part that includes an overhang that hangs over the opening, and
wherein, in said step (d), the ink is discharged until the ink is in contact with a bottom face of the overhang.

4. The manufacturing method for a color filter substrate according claim 1,
wherein the opening is a first opening,
wherein, in said step (c), the first opening and a second opening are defined by the bank,
wherein the bank has a lower part and an upper part,
wherein the upper part includes a first overhang that hangs over the first opening and a second overhang that hangs over the second opening,
wherein the ink is a first ink,
wherein, in said step (d), a second ink of a different color from the first ink is discharged in the second opening,
wherein the translucent region is provided in order to form the first overhang and the second overhang, and
wherein, of the translucent region, a transmittance of a region for forming the second overhang is different from a transmittance of a region for forming the first overhang.

5. The manufacturing method for a color filter substrate according claim 1,
wherein the opening is a first opening,
wherein, in said step (c), the first opening and a second opening are defined by the bank,
wherein the bank has a lower part and an upper part,
wherein the upper part includes a first overhang that hangs over the first opening and a second overhang that hangs over the second opening,
wherein the ink is a first ink,
wherein, in said step (d), a second ink of a different color from the first ink is discharged in the second opening,
wherein the translucent region is provided in order to form the first overhang and the second overhang, and
wherein, of the translucent region, a transmittance of a region for forming the second overhang is substantially the same as a transmittance of a region for forming the first overhang.

6. A color filter substrate, comprising:
a substrate;
a bank defining an opening; and
a color filter formed in the opening,
wherein the color filter and the bank are formed on the substrate,
wherein the bank has a lower part, and an upper part that includes an overhang that hangs over the opening, and
wherein the color filter has a shape that is convex in a direction opposite to the substrate, the color filter being in contact with a bottom face of the overhang.

7. The color filter substrate according to claim 6, wherein the bank does not include a liquid-repellent substance.

8. The color filter substrate according to claim 6,
wherein the opening, the color filter, and the overhang are respectively a first opening, a first color filter, and a first overhang,
wherein the bank further defines a second opening,
wherein the color filter substrate further includes a second color filter formed in the second opening and on the substrate,
wherein the upper part further has a second overhang that hangs over the second opening,
wherein a color of the second color filter differs from a color of the first color filter,
wherein the second color filter has a shape that is convex in a direction opposite to the substrate, the second color filter being in contact with a bottom face of the second overhang, and
wherein the second overhang has a different thickness from the first overhang.

9. The color filter substrate according to claim 6,
wherein the opening, the color filter, and the overhang are respectively a first opening, a first color filter, and a first overhang,
wherein the bank further defines a second opening,
wherein the color filter substrate further includes a second color filter formed in the second opening and on the substrate,
wherein the upper part further has a second overhang that hangs over the second opening,
wherein a color of the second color filter differs from a color of the first color filter,
wherein the second color filter has a shape that is convex in a direction opposite to the substrate, the second color filter being in contact with a bottom face of the second overhang, and
wherein the second overhang has substantially a same thickness as the first overhang.
